(19) United States
(12) Patent Application Publication
(10) Pub. No.: US 2013/0112559 A1
(43) Pub. Date: May 9, 2013

(54) DEVICE AND METHOD FOR HANDLING DROPS

(71) Applicant: Commissariat A L'Energie Atomique Et Aux Energies Alternatives, Paris (FR)

(72) Inventors: Raphael RENAUDOT, Saint-Etienne (FR); Vincent Agache, Champagnier (FR)

(73) Assignee: COMMISSARIAT A L'ENERGIE ATOMIQUE ET AUX ENERGIES ALTERNATIVES, Paris (FR)

(21) Appl. No.: 13/645,755

(22) Filed: Oct. 5, 2012

(30) Foreign Application Priority Data
Nov. 9, 2011 (FR) 11 60186

(51) Int. Cl. B81B 1/00

(52) U.S. Cl. 204/452; 204/601; 204/603; 204/451

(57) ABSTRACT

The invention relates to a microfluidic device and a method for handling at least one drop.

The device comprises first and second microfluidic surfaces (3a, 3b) parallel and separated from each other by a separation distance (H), at least one first electrical displacement path (5a) arranged on said first surface (3a), and at least one second electrical displacement path (5b) arranged on said second surface (3b). The at least one of the first and second paths is configured in order to form a respective fluidic finger along said path, said fluidic finger rupturing via capillarity, by generating at least one respective drop. The first and second paths are configured so that said separation distance between said first and second surfaces is on the one hand, greater than the fluidic thickness formed by each fluidic finger and, on the other hand, less than the fluidic thickness formed by each drop.

### TECHNICAL FIELD

This invention relates to the general field of forming and handling drops in a microfluidic device.

### PRIOR ART

In many fields, it is sought to form and handle drops for analysing liquid samples of small volumes in the simplest and least intrusive manner possible.

This can be the case, for example, in order to establish biological and/or chemical interactions between two solutions for a chemical analysis, a biological or medical diagnosis, or in the field of agri-food or genetic engineering.

For the purposes of illustration, biochips can be mentioned which constitute, in the field of molecular biology, microsystems for analysing the hybridisation of nucleic acids (DNA and/or RNA), or the interaction of the antigen/antibody, protein/ligand, protein/protein, enzyme/substrate, etc. type. It can then be sought to obtain the kinetic parameters or the equilibrium constants associated with these chemical and/or biological interactions.

In general, the handling of drops or fluidic flows can be carried out using hydrodynamic, electrical or magnetic means. Several techniques for handling can be used, such as, for example, handling through the effect of electrowetting and that through the effect of dielectrophoresis.

EWOD electrowetting (Electrowetting on Dielectric) allows multiple elementary fluidic operations to be carried out. This technique uses in general, a mat of electrodes that is sequentially switched according to a suitable control in order to make a drop advance closer and closer on a surface. The displacement of a drop via EWOD can be carried out by using a potential difference between an electrode on a cover and another electrode on a substrate. The drop is as such directly in contact with the two planes. It is also possible to displace a drop from one electrode to another by applying a potential difference between the anode electrode and the surrounding fluid. However, a drop possesses its own volume as soon as it is formed and either it never enters into contact with the facing plane or it is always in contact with the facing plane. This characteristic cannot be controlled. Likewise, this technique does not make it possible to form facing drops using different flows of liquids.

The dielectrophoresis method LDEP is used for forming drops on a surface. However, to date this technique has been applied in an open configuration (i.e. without a cover) or closed with configurations that are identical to the displacement of drops via EWOD (i.e. with a potential difference between a network of electrodes on a surface and an electrode representing the mass on the cover). In this configuration the liquid is in contact with the substrate and the cover.

There are several works that mention mechanisms for handling liquids on a surface through liquid dielectrophoresis.

Patent application WO2006025982 as well as the article by Ahmed and Jones entitled “Optimized liquid DEP droplet dispensing”, J. Micromech. Microeng., 17 (2007), 1052-1058 describe a device for forming drops via LDEP in an open configuration without a cover. This device consists of a microfluidic platform comprised of a substrate and of two coplanar electrodes covered with a dielectric material. An AC signal is applied between the two electrodes which consequently causes the displacement of a liquid on the platform.

Another application of U.S. Patent 20110056834 describes a closed microfluidic device comprising two similar facing LDEP platforms and separated from each other. The first platform (or substrate) comprises electrodes decoupled from each other and activated independently by an AC signal and the second platform (or cover) comprises an electrode playing the role of mass. This configuration allows for the displacement of the flows of liquid in several directions via the LDEP effect. However, the liquid needs to touch both the electrodes of the cover and of the substrate in order to be able to be displaced. As such, this device does not make possible the transfer of a liquid from one surface to another or the precise and reproducible forming and handling of drops.

The purpose of this invention is to overcome the aforementioned disadvantages by proposing a more effective and more precise device and method for the forming and handling of drops.

### DESCRIPTION OF THE INVENTION

The invention has for purpose a microfluidic device for handling a drop, comprising:
first and second parallel microfluidic surfaces and separated from each other by a separation distance,
at least one first electrical displacement path arranged on said first surface,
at least one second electrical displacement path arranged on said second surface, said first and second paths defining between them at least one crossover zone,
at least one of said first and second paths being configured in order to form through liquid dielectrophoresis, under the effect of an electrical activation, a respective fluidic finger along said path from corresponding reservoir of liquid of interest arranged in such a way as to be able to place into contact said liquid with the associated surface, said fluidic finger rupturing via capillarity under the effect of an electrical deactivation, by generating at least one respective drop from said fluidic finger in said at least one crossover zone,
the first and second paths being configured so that said separation distance between said first and second surfaces is on the one hand, greater than the fluidic thickness formed by each fluidic finger and, on the other hand, less than the fluidic thickness formed by each drop.

As such, a fluidic finger formed on one of the first and second paths will not be impacted by the other of said first and second paths while still allowing for the interaction of each of the first and second paths with the drop formed on one or the other of the first and second paths. This makes it possible to form and handle drops on one or several locations and on one or two surfaces for many applications that require transfers of drops from one plane to another or a mixture of drops for biological and/or chemical interactions between different solutions simultaneously.

When the two fluids are miscible, a mixture is obtained during the putting into contact of the two drops formed opposite each other. But by mixture, an association of immiscible liquids is also meant, the mixture then being two-phase, i.e. including two immiscible liquid phases, a liquid phase being for example encapsulated in a second liquid phase.

According to a first embodiment of this invention, said first electrical displacement path comprising a pair of first electrodes substantially parallel and coplanar arranged on said first surface for the forming under the effect of the electrical activation, of a first fluidic finger from a first reservoir of a first liquid of interest, said second electrical displacement path comprising a pair of second electrodes substantially parallel and coplanar arranged on said second surface for the forming under the effect of the electrical activation, of a second fluidic finger from a second reservoir of a second liquid of interest, said first and second fluidic fingers rupturing via capillarity under the effect of the deactivation, by generating at least one respective first drop and at least one second drop which are mixed in said at least one crossover zone in order to form at least one global drop.

This makes it possible to cross the first and second fluidic fingers, without coming into contact, and form drops coming from two different surfaces which however enter into contact. As such, this device is ideal for handling drops in order to carry out different applications that require for example interactions or reactions between two volumes of liquids.

Advantageously, said pair of first electrodes comprising a plurality of first drop forming zones, in such a way that the deactivation of said pair of first electrodes, the first fluidic finger ruptures into a plurality of first drops each located on one of said first drop forming zones.

This makes it possible to form drops in a reproducible manner at strategic locations of the first surface.

Advantageously, said pair of second electrodes comprising a plurality of second drop forming zones each arranged facing a first separate drop forming zone forming as such a plurality of crossover zones, in such a way that at the deactivation of said pair of second electrodes, the second fluidic finger ruptures into a plurality of second drops each located on one of said second drop forming zones, each second drop coming into contact with the first corresponding drop in order to form a global drop in the corresponding crossover zone.

This makes it possible to form mixtures between the drops of the first surface and those of the second surface in an entirely reproducible manner and at well-defined locations.

According to a particular configuration of the first embodiment, said first surface comprises a first network of m pairs of first electrodes each comprising a series of n first drop forming zones forming as such a first set of nm first drop forming zones, said second surface comprising a second network of n pairs of second electrodes each comprising a series of m second drop forming zones forming as such a second set of nm second drop forming zones, said nm first drop forming zones crossing over said nm second drop forming zones in order to form a set of nm crossover zones.

This makes it possible to cause a very large number of different drops to interact in a simultaneous and automated manner using at least two solutions.

Advantageously, said pair of second electrodes is configured to displace at least one second drop and/or at least one global drop located along said pair of second electrodes.

This makes it possible for example to use second electrodes that do not comprise zones for forming drops and displace a second drop in order to come into contact with a first corresponding drop located in a first drop forming zone of said pair of first electrodes in order to form a corresponding global drop. This also makes it possible to displace the second drops and/or the global drops for various chemical and/or biological protocols.

According to a second embodiment, said first electrical displacement path comprises a pair of substantially parallel and coplanar first electrodes arranged on said first surface for the forming through liquid dielectrophoresis under the effect of the electrical activation, of a fluidic finger from a reservoir of liquid of interest, said fluidic finger rupturing via capillarity under the effect of the deactivation, by generating at least one drop, said second electrical displacement path comprising second electrodes for the displacement of said at least one drop under the effect of an electrical activation of said second electrodes.

This makes it possible to form drops on a first surface, to transfer them onto another surface and to then displace them on this second surface in order to carry out various protocols for different biological and/or chemical applications.

Advantageously, the device comprises means of detecting a component of a drop formed on said at least one crossover zone.

This makes it possible to analyse the chemical and/or biological properties of the liquids.

According to a first alternative embodiment, said means of detecting are optical means comprising a light source in order to emit a light on said at least one drop and means of receiving in order to receive the light diffused by said at least one drop.

This makes it possible to handle and analyse samples in a reduced period of time in a simultaneous and precise manner.

According to another alternative, said means of detecting are electromechanical means comprising at least one flat oscillator of which a surface forms a detection surface belonging to one or the other of said first and second surfaces.

This makes it possible to have a simple, compact, and autonomous device for both handling and analysing samples effectively.

Advantageously, said detection surface has a hydrophilic zone intended to be covered by said at least one drop.

This makes it possible to place the liquid on the most sensitive locations of the detection surface for optimal detection.

Advantageously, each of said first and second electrodes is covered with a dielectric layer.

This makes it possible to prevent direct contact between the liquid and the electrodes in order to prevent electrolysis of the liquid.

The invention also relates to a method of handling a drop, comprising the following steps:
putting into contact of at least one first reservoir comprising a first liquid of interest with at least one first corresponding electrical displacement path arranged on a first microfluidic surface,
putting into contact of at least one second reservoir comprising a second liquid of interest with at least one second corresponding electrical displacement path arranged on a second microfluidic surface, said first and second surfaces being parallel and separated from each other by a separation distance, said at least one first and at least one second paths of displacement defining between them at least one crossover zone,
activation of said at least one first path of displacement, in such a way as to form along said first path a first corresponding fluidic finger,
activation of said at least one second path of displacement, in such a way as to form along said second path a second corresponding fluidic finger,
deactivation of said at least one first path of displacement, in such a way that the first corresponding fluidic finger is ruptured via capillarity by generating at least one first drop located in said at least one crossover zone,
deactivation of said at least one second path of displacement, in such a way that the second fluidic finger is ruptured via capillarity by generating at least one second drop located in said at least one crossover zone, said separation distance between said first and second surfaces being on the one hand, greater than the sum of the thicknesses of said first and second fluidic fingers, and, on the other hand, less than the sum of the thicknesses of said first and second drops, in such a way that said first and second drops are mixed together in said at least one crossover zone in order to form at least one global drop.

Advantageously, the method comprises the following steps:
putting into contact of a set of m first reservoirs comprising m first liquids of interest with a network of m first corresponding paths each comprising a series of n first drop forming zones forming as such a first set of nm first drop forming zones,
putting into contact of a set of n second reservoirs comprising n second liquids of interest with a network of n corresponding second paths each comprising a series of m second drop forming zones forming as such a second set of nm second drop forming zones, said nm first drop forming zones crossing over respectively said nm second drop forming zones in order to form a set of nm corresponding crossover zones,
activation of said network of m first paths, in such a way as to form a network of m first corresponding fluidic fingers,
activation of said network of n second paths, in such a way as to form a network of n second corresponding fluidic fingers,
deactivation of said network of m first paths, in such a way that the m first corresponding fluidic fingers rupture via capillarity by generating a set of nm first drops in said first set of nm first drop forming zones,
deactivation of said network of n second paths, in such a way that the n second corresponding fluidic fingers rupture via capillarity by generating a set of nm second drops in said second set of nm second drop forming zones, the nm first drops mixing with the nm second corresponding drops in order to form a set of nm global drops in the nm corresponding crossover zones.

Advantageously, said m first reservoirs include respectively m first samples of different properties of a first solution and said n second reservoirs include respectively n second samples of different properties of a second solution forming as such nm different global drops.

Advantageously, the method can comprise a detection via optical, electromechanical, or electrophysiological means of the different interactions between said first and second solutions.

The invention also relates to a method for handling a drop, comprising the following steps:
putting into contact of at least one reservoir comprising a liquid of interest with at least one first corresponding electrical displacement path arranged on a first microfluidic surface, said first surface being parallel to a second microfluidic surface and separated from the latter by a separation distance, said second surface comprising at least one second electrical displacement path defining at least one crossover zone with said at least one first path,
activation of said at least one first path of displacement, in such a way as to form along said first path a corresponding fluidic finger,
deactivation of said at least one first path of displacement, in such a way that the corresponding fluidic finger is ruptured by capillarity by generating at least one drop located in said at least one crossover zone, said separation distance between said first and second surfaces being on the one hand, greater than the thickness of said fluidic finger and, on the other hand, less than the thickness of said at least one drop, and
activation of said at least one second electrical displacement path, in such a way as to displace said at least one drop.

Other advantages and characteristics of the invention shall appear in the non-restricted detailed description below.

### BRIEF DESCRIPTION OF THE DRAWINGS

Embodiments of the invention shall now be described, by way of non-restricting examples, in reference to the annexed drawings, wherein:

FIG. 1 diagrammatically shows a microfluidic device for handling a drop, according to the invention;

FIG. 2 is a longitudinal cross-section diagrammatical view of a device for handling according to a first preferred embodiment of the invention;

FIGS. 3A and 3B are diagrammatical bottom views of the upper substrate of the device shown in FIG. 2;

FIGS. 3C and 3D are diagrammatical top views of the lower substrate of the device shown in FIG. 2;

FIG. 3E is a detailed view of a portion of the displacement electrodes of the device shown in FIG. 2;

FIG. 4A to 4C are diagrammatical longitudinal cross-section views of the device shown in FIG. 2, showing the forming of drops of liquid;

FIG. 5 is a diagrammatical view in perspective of the crossover zone of the device of FIG. 2;

FIGS. 6A to 6E diagrammatically show a device for handling drops, according to a particular configuration of the first preferred embodiment of the invention;

FIGS. 7A and 7B diagrammatically show a device for handling according to the configuration of FIG. 6A, comprising means of optical detection;

FIGS. 8A and 8B diagrammatically show a device for handling according to FIG. 6A, comprising means of electromechanical detection; and

FIG. 9 is a longitudinal cross-section diagrammatical view of a device for handling according to a second preferred embodiment of the invention.

### DETAILED DESCRIPTION OF PREFERRED EMBODIMENTS

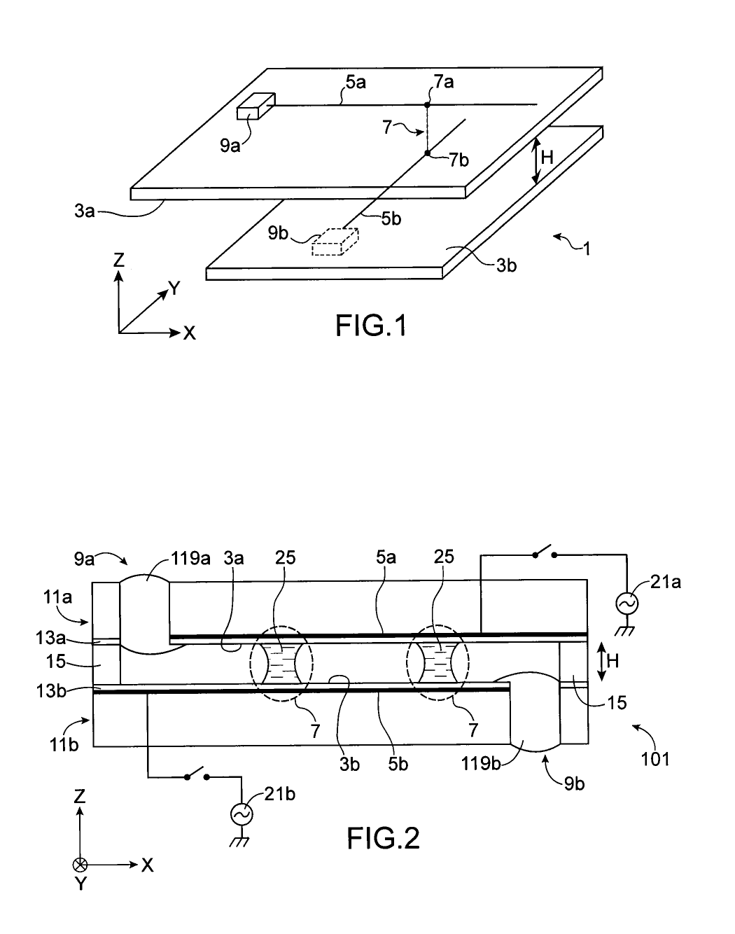

FIG. 1 diagrammatically shows a microfluidic device 1 for handling a drop, according to the invention.

The microfluidic device for handling 1 comprises a first microfluidic surface 3a and a second microfluidic surface 3b. The first and second surfaces 3a, 3b are parallel to each other and separated from each other by a separation distance H.

In all of the description which shall follow, by convention, a direct orthonormed system in Cartesian coordinates (X, Y, Z) shown in FIG. 1 is used. The plane (X, Y) is parallel to said first and second surfaces 3a, 3b and the direction Z is oriented starting from the second surface 3b towards the first surface 3a.

At least one first electrical displacement path 5a is arranged on the first surface 3a (here, a single first path is shown).

Likewise, at least one second electrical displacement path 5b is arranged on the second surface 3b (here, a single second path is illustrated).

By electrical path is meant either a continuous electrode, extending according to a given direction, or a plurality of adjacent elementary electrodes. In this latter case, each electrode is separated from its neighbour by a close spacing, with this spacing being typically of 1 μm for a width of the electrode of 10 μm, with the width being the dimension according to a direction perpendicular to that of the spacing.

The first and second electrical displacement paths 5a, 5b define between them at least one facing crossover zone 7, without contact. In other terms, they are not in contact with each other.

Indeed, the first and second paths 5a, 5b are arranged in such a way that there is a least one straight line (according to the direction Z) orthogonal to the first and second surfaces 3a, 3b intercepting the first path 5a at a first point 7a and the second path 5b at a second point 7b in such a way that the space formed between these two points defines the crossover zone 7. The distance between the first and second points 7a, 7b is of course, equal to the separation distance H.

Note that the directions in the plane (X, Y) of the first and second paths 5a, 5b can be secant according to any angle whatsoever forming a single crossover zone 7 (FIG. 1) or, confounded thus forming an infinity of crossover zones.

The at least one of the first and second paths 5a, 5b is configured in order to form through liquid dielectrophoresis, under the effect of an electrical activation, a respective fluidic finger along the path.

Through liquid dielectrophoresis (LDEP) is meant the application of an electrical force on an electrically insulating or conductive liquid, with the force being generated by a non-uniform oscillating electric field. The formation of a fluidic finger through liquid dielectrophoresis is in particular described in the article by Jones entitled “Liquid dielectrophoresis on the microscale”, J. Electrostat, 51-52 (2001), 290-299. When the liquid is located in an electric field, the molecules of the liquid acquire a non-zero dipole and become polarised. Insofar as the field is not uniform, a Coulomb force appears and induces the displacement of the molecules of the liquid, and as such of a all the liquid, towards a field maximum.

The fluidic finger is formed along the respective path 5a, 5b from a reservoir 9a, 9b of corresponding liquid of interest arranged in such a way as to be able to place into contact the liquid with the associated surface 3a, 3b. FIG. 1 shows a first reservoir 9a arranged on the first surface 5a and possibly a second reservoir (shown as a dotted line) 9b arranged on the second surface 3b.

Note that, when the electrical control is stopped, the fluidic finger has an unstable form. A capillary instability then develops quickly and causes the rupture of the finger into one or several drop(s), which makes it possible to lower the surface energy of the liquid.

As such, each fluidic finger formed on the first surface 3a and/or the second surface 3b is ruptured via capillarity under the effect of an electrical deactivation, by generating a respective drop or drops in the crossover zone(s) 7.

Moreover, the first and second paths 5a, 5b are configured so that the separation distance H between the first and second surfaces 3a, 3b is on the one hand, greater than the fluidic thickness formed by each fluidic finger and, on the other hand, less than the fluidic thickness formed by each drop.

As such, when a single one of the paths 5a, 5b is configured to form a fluidic finger, the separation distance H is such that the fluidic finger does not touch the other path while at least one of the drops generated by this finger is touching this other path.

Moreover, when the first and second paths 5a, 5b are configured to form first and second fluidic fingers respectively, the separation distance H is such that the fluidic fingers do not touch while at least one of the drops generated by the first finger is toughing another drop among the drops generated by the second finger.

FIG. 2 shows a microfluidic device for handling a drop according to a first embodiment of the invention.

The device for handling 101 comprises an upper substrate 11a forming a cover and a lower substrate 11b, arranged opposite one another. The terms “lower” and “upper” are here to be understood in terms of orientation according to the direction Z of the orthonormed system (X, Y, Z).

The cover 11a has a lower surface formed of a dielectric layer 13a. The free surface of the dielectric layer 13a corresponds to the first surface 3a.

The lower substrate 11b has an upper surface formed of a dielectric layer 13b. The free surface of the dielectric layer 13b corresponds to the second surface 3b.

The material of the lower 11b or upper 11a substrate can be chosen from among the following materials: glass, pyrex or an organic material such as polycarbonate or PEEK, monocrystalline silicon, polycrystalline silicon, diamond, silicon nitride, silicon oxide, nickel, tungsten, and even platinum. The upper substrate 11a is advantageously made from a transparent material. The thickness of the upper 11a or lower 11b substrate can be between a few tens of microns and a few millimetres.

The device 101 comprises separation walls 15 of height H in order to provide a regular and precise separation distance H between the first and second surfaces 3a, 3b of the two substrates 11a and 11b. The material of the separation walls 15 can be, for example, polymer, resin, dry films, or silicon.

The upper substrate 11a comprises a first reservoir 9a formed for example, by a first through-hole 9a and opening onto the first surface 3a. The first hole 9a can be filled with a first liquid of interest 119a.

The lower substrate 11b comprises a second through-hole 9b and opening onto the second surface 3b. The hole 9b can be filled with a second liquid of interest 119b, forming as such a second reservoir 9b of liquid of interest 119b.

The liquid has any such electrical conductivity. Advantageously for the actuating of the liquid via LDEP and the setting in place of the non-uniform electrical signal this conductivity is less than 100 mS·m⁻¹, and even less than 1 mS·m⁻¹.

The device for handling 101 comprises electrical means of forming fluidic fingers through liquid dielectrophoresis. More particularly, the lower and upper substrates 11a, 11b include respectively first and second electrical displacement paths 5a, 5b in order to form fluidic fingers through liquid dielectrophoresis on respectively the first and second surfaces 3a, 3b. The direction of the first path 5a is shown, by way of example, parallel with that of the second path 5b forming as such a plurality of crossover zones 7.

Note that the electrical means are similar to those presented in the article by Ahmed and Jones entitled “Optimized liquid DEP droplet dispensing”, J. Micromech. Microeng., 17 (2007), 1052-1058.

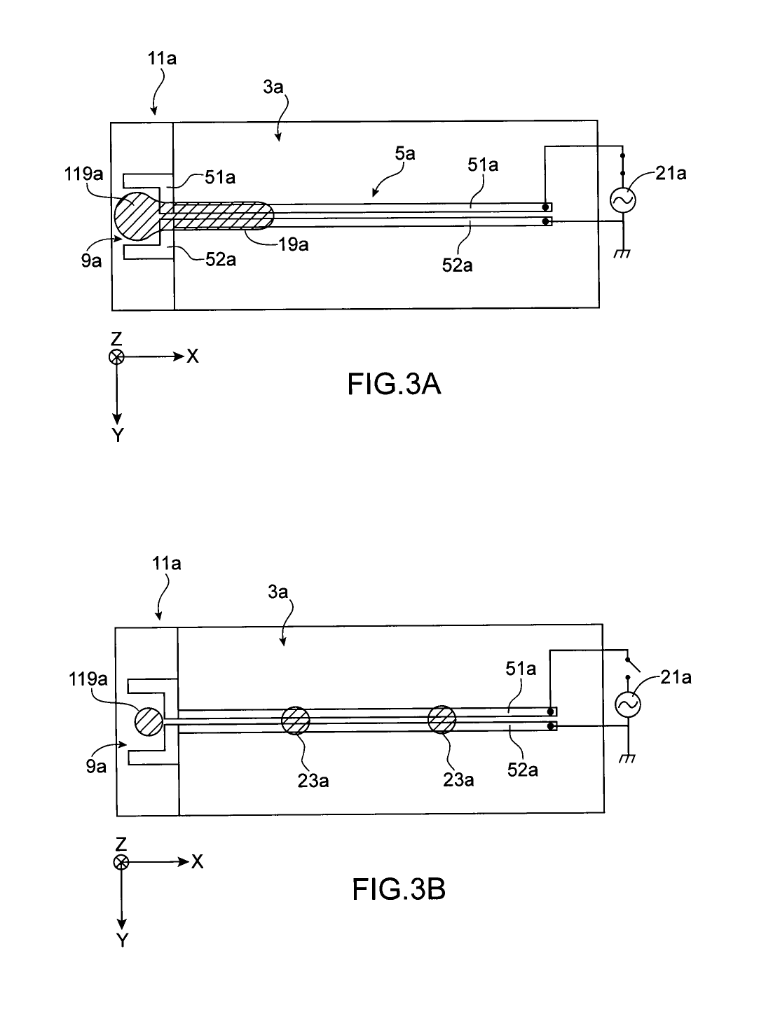

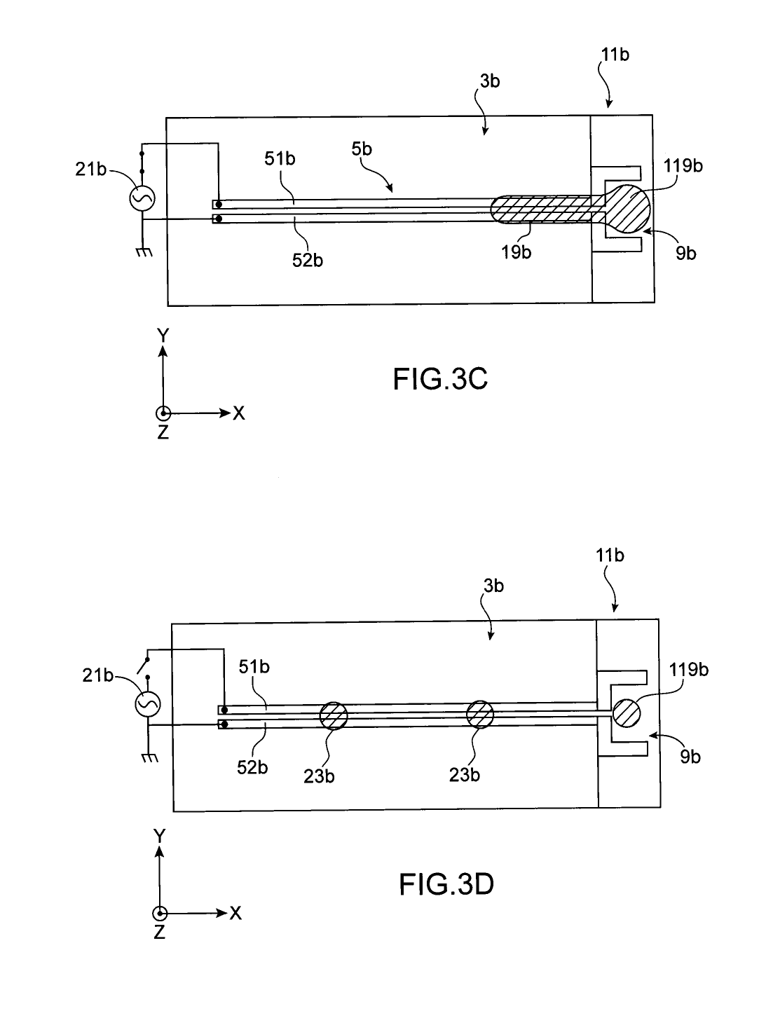

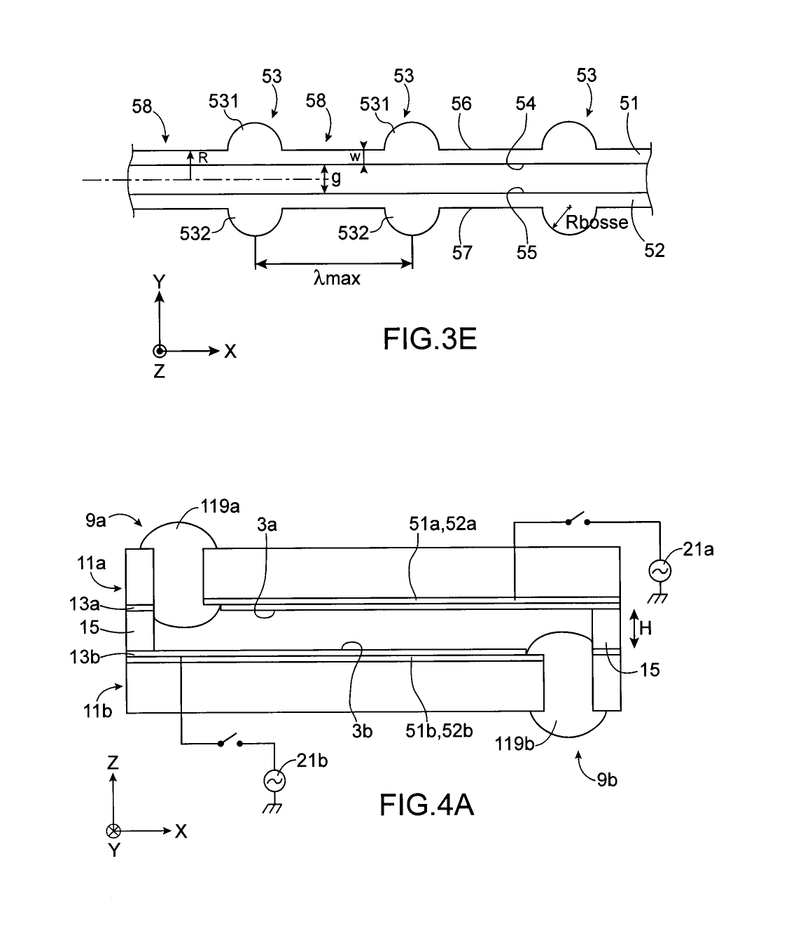

As such, as shown in FIG. 3A, the first electrical displacement path 5a comprises a pair of first displacement electrodes 51a, 52a arranged on the first surface 3a. The first electrodes 51a and 52a are parallel to each other, coplanar and substantially rectilinear.

Likewise, as shown in FIG. 3C, the second electrical displacement path 5b comprises a pair of second electrodes 51b, 52b of displacement arranged on the second surface 3b. The second electrodes 51b and 52b are parallel to each other, coplanar and substantially rectilinear.

The first and second displacement electrodes (51a, 52a 51b, 52b) are pockets made of a metal material, for example, gold or aluminium.

The first dielectric layer 13a which forms the first surface 3a or the second dielectric layer 13b which forms the second surface 3b can be, for example, a SiO₂ oxide, nitride (SiN, Si₃N₄), resins, dry films, SiOC, hydrophobic polymers of the Teflon type (registered trademark—tetra-fluoroethylene) or others fluoropolymers, a polymer of poly-p-xylylene (parylene) a High-k oxide deposited via the so-called ALD method (HfO₂, Al₂O₃, ZrO₂, SrTiO₃, BaTiO₃, Ba₍₁₋ₓ₎SrₓTiO₃ (BST) . . . ), and have a thickness between a few nm (for example 10 nm or 25 nm) and a few microns (for example 5 μm). This makes it possible to prevent the electrolysis of the liquid if the latter were in direct contact with the displacement electrodes (51a, 52a 51b, 52b).

With regards to the space of separation H, the dimensions of the first and second electrodes 51b, 52b (i.e. length and width of each electrode, and difference between each pair of electrodes) are chosen in such a way that on the one hand, the sum of a maximum thickness of a first finger to be formed on the first surface 3a and of a maximum thickness of a second finger to be formed on the second 3b surface is less than the separation distance H and, on the other hand, the sum of a radius of a first drop to be formed on the first surface 3a and of a second drop to be formed on the second surface is greater than the separation distance H.

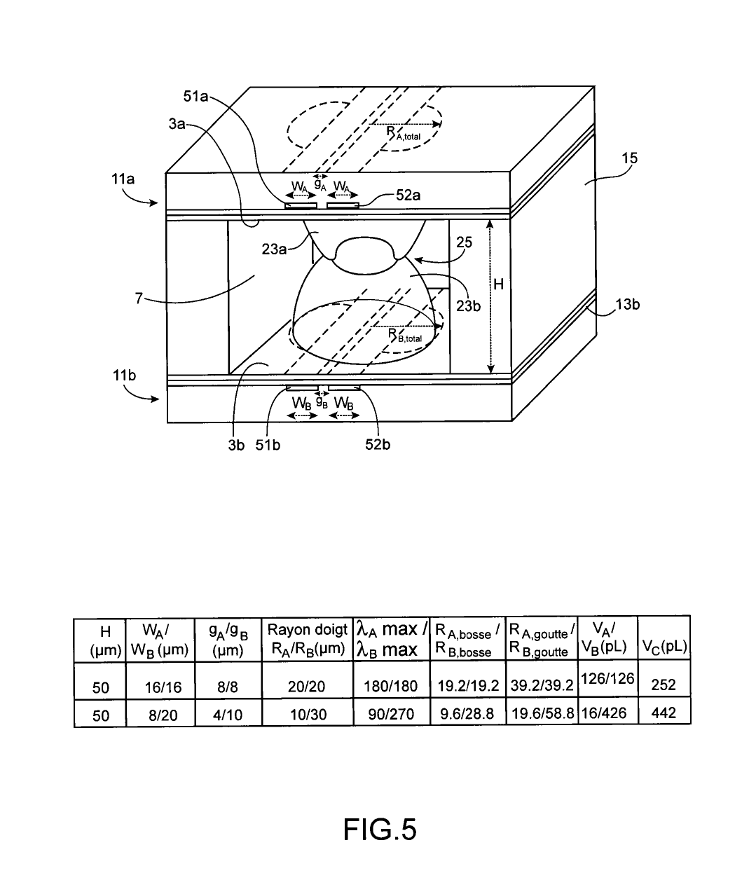

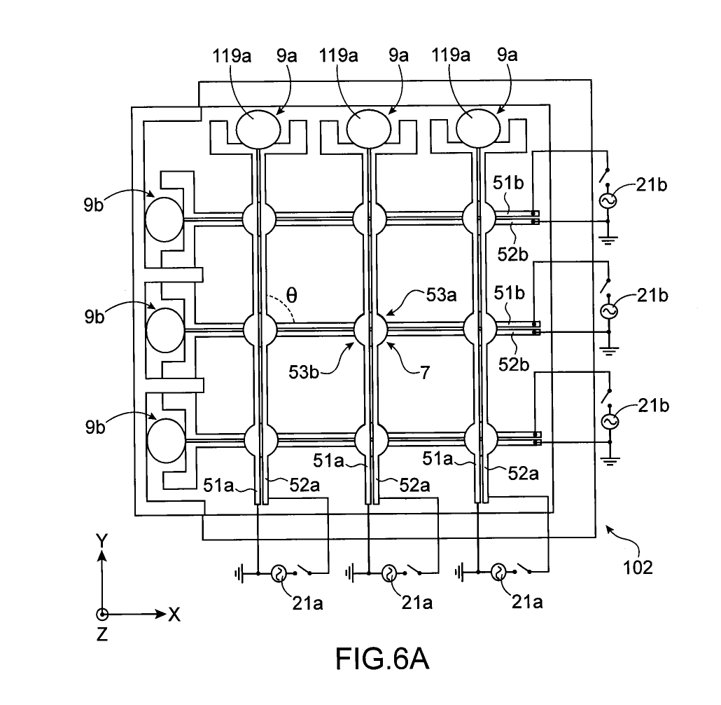

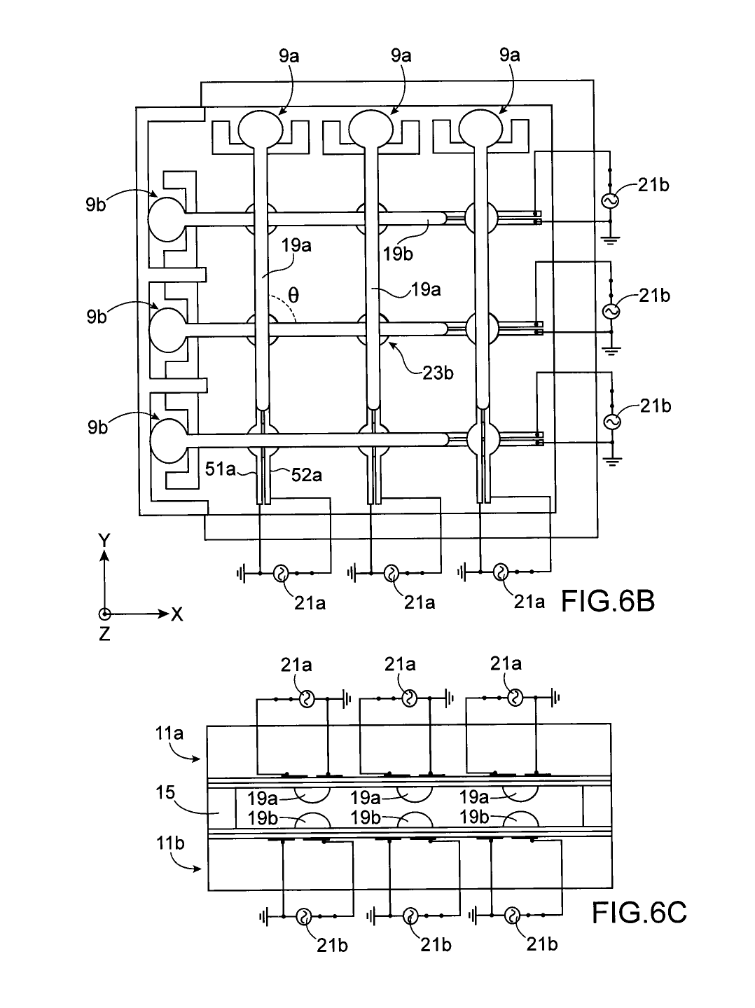

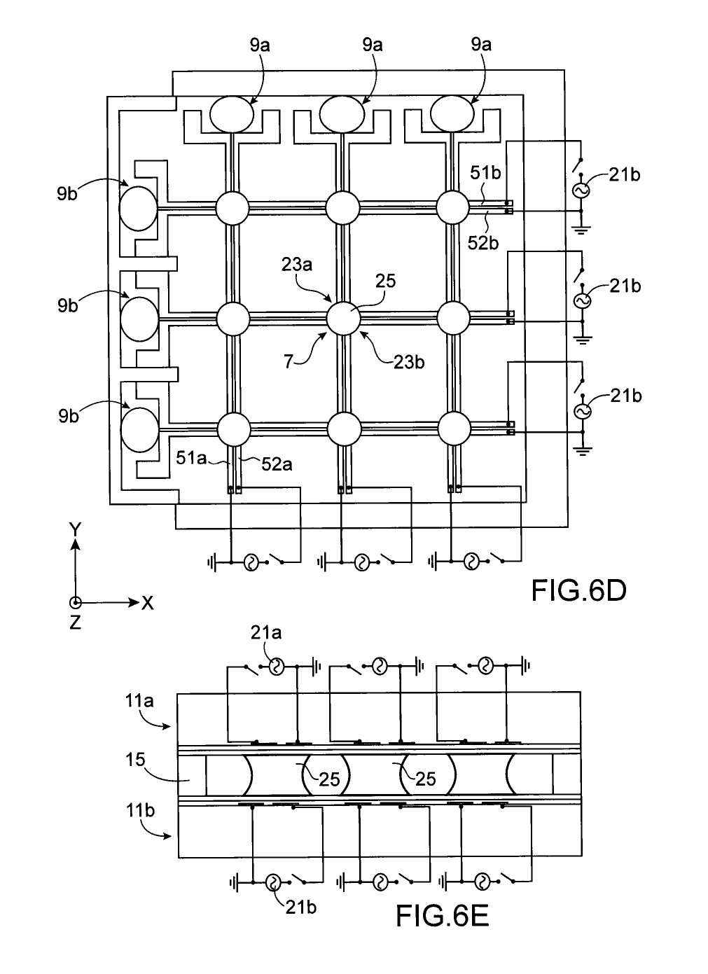

As such, a first fluidic finger 19a formed on the first surface 3a does not come into contact with a second fluidic finger 19b formed on the second surface 3b (see FIGS. 6B and 6C). However, when a first drop on the first surface 3a and a second drop on the second surface 3b are formed in the same crossover zone (i.e. with the same coordinates (x, y)), the latter come into contact (see FIGS. 5, 6D and 6E).

The first displacement electrodes 51a, 52a are connected to a first voltage generator 21a (FIG. 3A) making it possible to apply a first potential difference between these electrodes 51a, 52a. Likewise, the second displacement electrodes 51b, 52b are connected to a second voltage generator 21b (FIG. 3C) making it possible to apply a second potential difference between these electrodes 51b, 52b. The first generator and the second generator can be confounded: there is then a single generator, able to apply different signals to each pair of electrodes. In this latter case, the two pairs of electrodes (51a-51b and 52a-52b) can also be powered by the same signal.

The first or the second tension applied is an alternating voltage of which the frequency is between, for example, a few hertz (for the least conductive liquids) and a few megahertz, for example between 10 kHz and 10 MHz, and of a preferred voltage of a few volts RMS to a few hundred volts RMS. When the liquid is highly insulating, with for example a conductivity less than 10⁻⁹ S·m⁻¹, the frequency is of a magnitude of the Hz.

As such, under the effect of the electrical activation of the first electrodes 51a, 52a by the first generator 21a, a first fluidic finger 19a is formed on the pair of first electrodes 51a, 52a from the first reservoir 9a of first liquid of interest 119a (FIG. 3A).

Likewise, under the effect of the electrical activation of the second electrodes 51b, 52b by the second generator 21b, a second fluidic finger 19b is formed on the pair of second electrodes 51b, 52b from the second reservoir 9b of second liquid of interest 119b (FIG. 3C). Advantageously, the electrical activations are carried out simultaneously on the two surfaces. And further advantageously, the electric deactivation is carried out simultaneously on the two surfaces.

Moreover, as shown in FIGS. 3B and 3D, under the effect of the electrical deactivation (open circuits) of the first 51a, 52a and second 51b, 52b electrodes, the first and second fluidic fingers 19a, 19b rupture via capillarity, by generating at least one respective first drop 23a and at least one second drop 23b which are mixed together in at least one crossover zone 7 in order to form at least one global drop 25 (FIG. 2).

Advantageously, as shown in FIG. 3E, the pair of first displacement electrodes 51a, 52a (or respectively the pair of second displacement electrodes 51b, 52b) comprises a plurality of first drop forming zones (or respectively a plurality of second drop forming zones).

More particularly, FIG. 3E shows a pair of displacement electrodes 51, 52 (representing the first or second displacement electrodes) comprising a plurality of zones for forming a drop 53, in such a way that at the deactivation of the electrodes 51, 52, the fluidic finger ruptures into a plurality of drops each located on one of these zones for forming a drop 53.

Indeed, each electrode 51, 52 comprises an inside edge 54, 55 and an outside edge 56, 57. The inside edges 54, 55 are arranged opposite one another.

Advantageously, the zones for forming a drop 53 are formed of planar protuberances, or flat bumps 531 and 532, which extend towards the outside of each electrode of displacement 51, 52. The bumps 531 and 532 are a portion of the electrodes 51, 52 and are coplanar with the latter.

The bumps 531 and 532 are here arranged symmetrically in relation to one another and each belong to a different displacement electrode 51, 52.

As such, the displacement electrodes 51, 52 comprise rectilinear portions 58 and zones for forming a drop 53 connected together by said rectilinear portions 58.

The inside edges 54, 55 of the displacement electrode 51, 52 are separated from each other by a distance g. The rectilinear portions 58 have a width noted as w and consequently, the width (i.e. the radius in the plane (Y, Z)) of the fluidic finger is given by R=w+g/2. Each bump 531 and 532 is a half-disc with radius R_{bump} in the plane (X, Y) and of which the centre is located in the continuity of the outside edge 56, 57 of the rectilinear portions 58. As shall be discussed in more detail further on, the radius R_{bump} of a bump is of a magnitude of the radius R of the fluidic finger.

It is supposed that the section of the fluidic finger in the vertical plane (Y, Z) is semi-circular, and that its surface is invariable along electrodes. When the width w of the electrodes is of the same magnitude as their spacing g, the fluidic finger at all points of the path covers a zone inscribed between the two lateral ends of the electrodes. 2R denotes the distance separating these two rectilinear ends (i.e. the outside edges 56, 57 of the rectilinear portions 58 of the displacement electrodes 51, 52).

More preferably, the zones for forming a drop 53 are arranged at an equal distance from each other, more preferably between 8R and 10R, and more preferably at the distance 9.016R.

As shall be discussed in more detail further on, the spacing distance between the zones for forming a drop 53 is substantially equal to the most unstable wavelength λₘₐₓ of the fluidic finger which extends along displacement electrodes 51, 52.

Further advantageously, the pair of first electrodes 51a, 52a comprises a plurality of first drop forming zones 53 and the pair of second electrodes 51b, 52b comprises a plurality of second drop forming zones 53 (see FIG. 5).

At the deactivation of the first electrodes 51a, 52a, the first fluidic finger 19a ruptures into a plurality of first drops 23a each located on one of these first drop forming zones 53.

Likewise, at the deactivation of the second electrodes 51b, 52b, the second fluidic finger 19b ruptures into a plurality of second drops 23b each located on one of these second drop forming zones 53.

The second drop forming zones 53 are arranged each facing a separate first drop forming zone 53 forming as such a plurality of crossover zones 7 in such a way that at the deactivation of the first 51a, 52a and second 51b, 52b electrodes, each second drop 23b comes into contact with the first corresponding drop 23a in order to form a global drop 25 in the corresponding crossover zone 7. This makes it possible to form entirely reproducible mixtures between the drops of the first surface 3a and those of the second surface 3b. By reproducible is meant the volume of the mixture and its location are controlled.

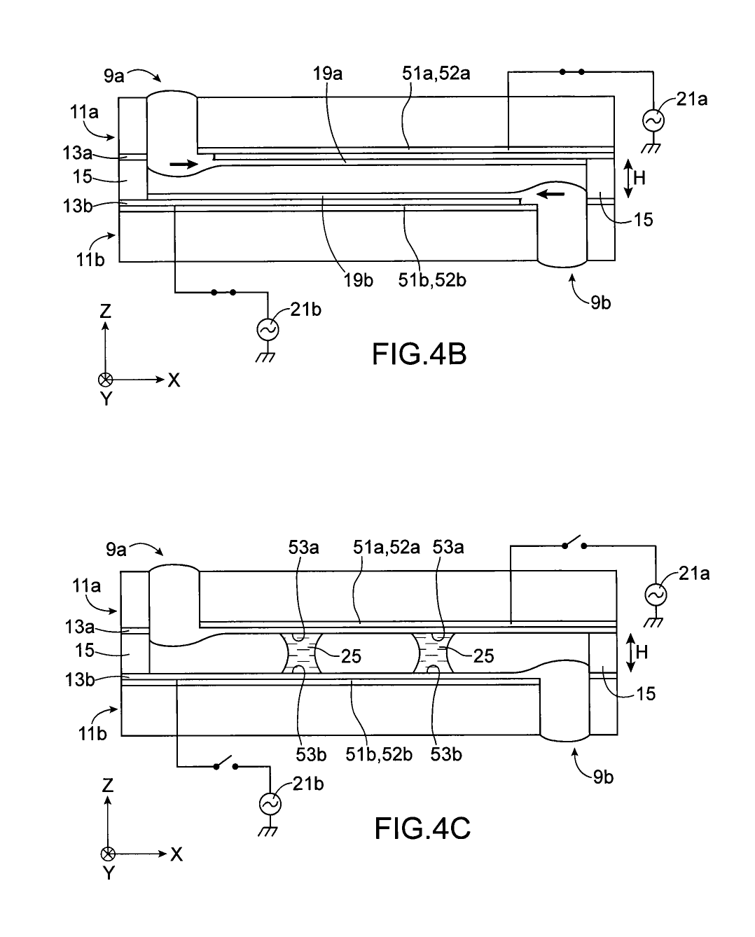

The operation of the device for handling 101 according to for example the configuration of FIG. 3E (i.e. with displacement electrodes comprising a plurality of zones for forming a drop) is as follows, in reference to FIGS. 4A to 4C.

According to a first step (FIG. 4A), the first liquid of interest 119a is placed into contact with the first surface 3a, from the first reservoir 9a.

Likewise, the second liquid of interest 119b is put into contact with the second surface 3b, from the second reservoir 9b.

A first non-uniform and oscillating electric field is generated (FIG. 4B), under the effect of a first electrical control, by applying a voltage adapted to the two first displacement electrodes 51a, 52a.

The first fluidic finger 19a extends along two first displacement electrodes 51a, 52a.

The first fluidic finger 19a substantially covers the first displacement electrodes 51a, 52a over their entire length, and has a contact width (in the plane (X, Y)) substantially equal to the distance 2R defined previously and corresponding to the distance separating the outside edges of the first electrodes 51a, 52a, in their rectilinear portion.

Likewise, a second non-uniform and oscillating electric field is generated (FIG. 4B), under the effect of an electric control, by applying a voltage adapted to the two second displacement electrodes 51b, 52b.

The second fluidic finger 19b extends along two second displacement electrodes 51b, 52b substantially covering the second electrodes over their entire length.

Then, at the stopping of the first electrical control (FIG. 4C), the first fluidic finger 19a is ruptured via capillarity into a plurality of first drops each located on a first drop forming zone.

Likewise, at the stopping of the second electrical control (FIG. 4C), the second fluidic finger 19b is ruptured via capillarity into a plurality of second drops each located on a second drop forming zone.

Indeed, the fluidic finger 19a, 19b, in the absence of electrostatic force, is naturally unstable. The finger ruptures under the effect of a hydrodynamic instability of the Rayleigh-Plateau type. This fracturing of the finger into a plurality of drops makes it possible indeed to decrease the surface energy of the liquid.

The instability is a capillarity/inertia competition and the most unstable wavelength is such that kₘₐₓ·R=1/\sqrt{2}, where kₘₐₓ is the number of waves.

The most unstable wavelength is therefore written as λₘₐₓ=9.016R, R being the radius of the fluidic finger.

As such, the zones for forming a drop (53a, 53b) are separated from each other by a distance substantially equal to λₘₐₓ. These zones for forming a drop make it possible to deform the interface of the fluidic finger 19a, 19b at the wavelength λₘₐₓ, and as such to “preselect” the desired wavelength.

As such, the drops are formed simultaneously and are each located in a drop forming zone 53a, 53b.

Each drop has a calibrated volume. The volume depends on the width 2R of the fluidic finger 19a, 19b, the distance λₘₐₓ between the zones for forming a drop 53a, 53b and the radius R_{bump} of the protuberances, or bumps 531, 532, though the following equation:

$$\frac{2 π}{3} {( {R}_{bump} + R )}^{3} \approx \frac{π}{2} {R}^{2} {λ}_{max} + \frac{2 π}{3} {R}_{bump}^{3}$$

λₘₐₓ is substituted according to R in the equation hereinabove in order to result in a relation expressing R_{bump} according to R in the following manner:

R_{bump}=0.96×R˜R

The spacing distance H between the first surface 3a and the second surface 3b, as well as the lateral dimensions g and w and possible R_{bump} of the displacement electrodes 51, 52 are adapted in such a way that the maximum thickness of the first and second fingers is less than the distance H and that the sum of the radiuses of the first and second drops have a thickness greater than this distance H.

In other terms, let the radiuses (in the plane (Y, Z)) of the first and second fluidic fingers 19a, 19b be respectively R_{A} and R_{B}, then the radiuses of the first and second drops 23a, 23b is of a magnitude of 2R_{A} and 2R_{B} respectively. In this case (FIG. 5), the height H separating the first and second surfaces verifies the following inequality:

R_{A}+R_{B}<H<2R_{A}+2R_{B}.

Indeed, FIG. 5 is a diagrammatical view in perspective of the crossover zone of the device of FIG. 2.

The numerical examples given in the table associated with FIG. 5 show that for a separation distance H of a magnitude of 50 μm, the first electrodes 51a, 52a can have a width w_{A} of a magnitude of 8 μm to 16 μm and be separated from each other by a distance g_{A} of a magnitude of 4 μm to 8 μm, and that the second electrodes 51b, 52b can have a width w_{B} of a magnitude of 16 μm to 20 μm and be separated from each other by a distance g_{B} of a magnitude of 8 μm to 10 μm.

Thus, the radius R_{A} of the first fluidic finger is of a magnitude of 10 μm to 20 μm (R_{A}=w_{A}+g_{A}/2), the distance λ_{A,max} between the first drop forming zones is of a magnitude of 90 μm to 180 μm, the radius R_{A,bump} of the half-disc is of a magnitude of 9.6 μm to 19.2 μm, the radius R_{A,drop} (i.e. R_{A,total}) of the first drop 23a is of a magnitude of 19.6 μm to 39.2 μm, and the volume V_{A} of the first drop is of a magnitude of 16 pL to 126 pL.

Furthermore, the radius R_{B} of the second fluidic finger is of a magnitude of 20 μm to 30 μm, the distance λ_{B,max} between the second drop forming zones is of a magnitude of 180 μm to 270 μm, the radius R_{B} of the half-disc is of a magnitude of 19.2 μm to 28.8 μm, the radius R_{B,drop} (i.e. R_{B,total}) of the second drop is of a magnitude of 39.2 μm to 58.8 μm, the volume V_{B} of the second drop 23b is of a magnitude of 126 pL to 426 pL, and the volume V_{C} of the global drop is of a magnitude of 252 pL to 442 pL.

As such, the first and second drops 23a, 23b have a sufficient thickness so that the first drops 23a of the first surface 3a come into contact with the second corresponding drops 23b of the second surface 3b forming as such corresponding global drops 25.

The method according to the invention makes it possible to form drops rapidly and to handle them with precision in order to create interactions between different solutions of interest.

Note that the forming of a fluidic finger 19a, 19b is indeed very rapid, with a speed of displacement of the liquid by a magnitude of 1 to 10 cm/s; only 50 to 500 ms is needed to form a fluidic finger of 5 mm. In addition, the drops are formed even more rapidly, insofar as the characteristic time of a capillarity/inertia instability is \sqrt{ρR³/σ}, which is less than 0.01 ms for a liquid density of ρ=1000 kg/m³, a half-width R of a finger of a magnitude of a few tens of micrometres and a liquid/air surface tension σ=0.072 Nm.

Note that the zones for forming a drop 53 can be carried out on only one of the first and second surfaces 3a, 3b. As such, drops are formed at the desired locations (i.e. on electrodes provided with protuberances) and the liquid can again be displaced thanks to the facing electrodes that do not have any protuberances.

By way of example (not shown), the pair of first displacement electrodes 51a, 52a can include a plurality of first drop forming zones 53a, while the pair of second electrodes 51b, 52b does not have any.

As such, after the deactivation of the first electrodes 51a, 52a, the first fluidic finger 19a ruptures into a plurality of first drops 23a each located on one of these first drop forming zones 53a. Then, the pair of second electrodes 51b, 52b can be activated in order to displace at least one second drop 23b along these second electrodes, in order to come into contact with a first corresponding drop 23a located in a first drop forming zone 53 in order to form a global drop 25. Furthermore, the pair of second electrodes 51b, 52b can be activated in order to then displace the global drop 25 as such formed along second electrodes.

This makes it possible for example to use solvents playing the role of extractor on the first surface of the upper substrate while the ionic liquids are displaced on the second surface of the lower substrate in order to create a liquid-liquid extraction.

FIGS. 6A-6E diagrammatically show a microfluidic device for handling drops, according to a particular configuration of the first preferred embodiment of the invention.

The first surface 3a comprises a first network of m pairs of first electrodes 51a, 52a each comprising a series of n first drop forming zones 53a forming as such a first set of nm first drop forming zones 53a. The device 102 comprises also a set of m first reservoirs 9a of m first liquids of interest 119a arranged in such a way as to be able to place into contact respectively the m first liquids of interest 119a with the m pairs of first electrodes 51a, 52a.

The second surface 3b comprises a second network of n pairs of second electrodes 51b, 52b each comprising a series of m second drop forming zones 53b forming as such a second set of nm second drop forming zones 53b. Furthermore, the device comprises a set of n second reservoirs 9b of n second liquids of interest 119b arranged in such a way as to be able to place into contact respectively the n second liquids of interest 119b with the n pairs of second electrodes 51b, 52b.

The nm first drop forming zones 53a are arranged in such a way as to cross the nm second drop forming zones 53b in order to form a set of nm crossover zones 7.

More particularly, the top view of the device 102 shown in FIG. 6A shows three (m=3) pairs of first electrodes 51a, 52a each comprising three (n=3) first drop forming zones 53a as well as three (n=3) pairs of second electrodes 51b, 52b each comprising three (m=3) second drop forming zones 53b.

The first electrodes 51a, 52a of the first surface 3a can form in relation to the electrodes 51b, 52b of the second surface 3b any angle θ as long as the separation distance H is correctly dimensioned in relation to the widths w_{A}, w_{B} and differences g_{A}, g_{B} of the pairs of electrodes so that the inequality (R_{A}'R_{B})<H<(2R_{A}+2R_{B}) is satisfied.

In the initial state, the initial drops of the m first liquids of interest 119a are located in the m first reservoirs 9a at the beginning of the paths of the m pairs of first electrodes 51a, 52a. Likewise, the initial drops of the n second liquids of interest 119b are located in the n second reservoirs 17b at the beginning of the paths of the n pairs of second electrodes 51b, 52b.

FIG. 6B (top view) and FIG. 6C (cross-section view) show that when a signal oscillating with an adequate frequency and voltage tension is sent by a source of alternating voltage 21a, 21b on the first 51a, 52a and second 51b, 52b electrodes, first and second fluidic fingers 19a, 19b are set into motion along electrodes without coming into contact. After a certain very short period of time (of a magnitude of a few tens of milliseconds), the fluidic fingers 19a, 19b reach the ends of the electrodes. The profile of the fingers is a semi-disc and has for radius R_{A} for the first fingers and R_{B} for the second fingers.

FIG. 6D (top view) and FIG. 6E (cross-section view) show that as soon as the electrical circuit is opened and the electrodes (51a, 52a, 51b, 52b) are no longer powered, the liquid acts in such a way as to return to a state of minimum energy by retracting towards the protuberances (zones for forming a drop). As such, nm first drops 23a of a radius of approximately 2R_{A} are formed on the nm first drop forming zones 53a and nm second drops 23b of a radius of approximately 2R_{B} are formed on the nm second drop forming zones 53b.

As such, each of the nm first drops 23a coming from the first surface 3a interacts with the corresponding drop 23b of the nm second drops coming from the second surface 3b in order to form a set of nm global drops 25 in the nm crossover zones 7.

This makes it possible to create mixtures of biological components (for example, strands of DNA) or chemical components in very large quantities, simultaneously, in a very short period of time.

Solvents playing the role of extractor can also be used on the first surface of the upper substrate while the ionic liquids are displaced on the second surface of the lower substrate.

The device can also be used to form a network of solid pillars with reconfigurable geometry. In this case, the liquids displaced are for example, waxes or paraffins which have interesting fusion and solidification properties.

Advantageously, the device for handling comprises means of detecting a component of a drop formed on at least one crossover zone. These means of detecting can be optical, electromechanical, chemical or other means.

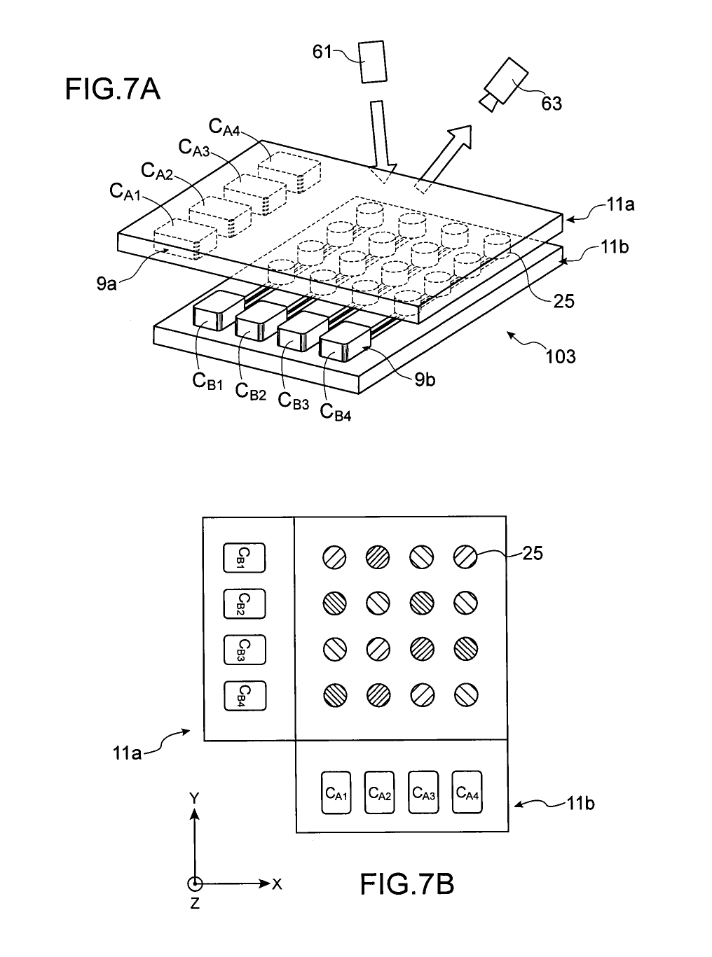

The FIGS. 7A and 7B diagrammatically show a device for handling according to a configuration of FIGS. 6A-6E, and comprising means of optical detection.

This device 103 is a microfluidic chip comprising an upper substrate 11a made from a transparent material and coupled to means of optical detection 61, 63. These means include a light source 61 lighting the global drop or drops 25 through the transparent substrate 11a and a sensor, or means of receiving 63 light in order to receive the light diffused by this or these drops 25. As such, the light diffused by a drop makes it possible to analyse the interaction which is produced inside this drop.

This example shows the creation of a fluorescence response map on n² chemical/biological reactions (here n=4) using 2n samples in an automated and simultaneous manner.

Indeed, using two biological or chemical solutions A and B comprising respectively chemical or biological elements α and β, nα samples (C_{A1}, C_{A2}, C_{A3}, C_{A4}) of the solution A are prepared in the first reservoirs 9a, and n_{β} samples (C_{B1}, C_{B2}, C_{B3}, C_{B4}) of the solution B in the second reservoirs 9b, with different properties for each sample (for example, in concentrations of the product).

With the device for handling 103, in a simultaneous and automated manner n_{α}·n_{β} global drops 25 that differ from each other are formed from the interaction between the nα first drops and n_{β} second corresponding drops.

With the means of emitting 61, a light excitation is sent which will be diffused by the various global drops 25. The light diffused and captured by the means of receiving 63 makes it possible to determine with precision the fluorescence responses of the interactions or reactions between the elements α and β (FIG. 7B).

According to an alternative embodiment, the means of detecting are electromechanical means. In this case, the device for handling comprises at least one detector on at least one of the upper and lower substrates. The detector can be a flat electromechanical oscillator arranged on a crossover zone and of which a surface forms a detection surface belonging to one or the other of the first and second surfaces.

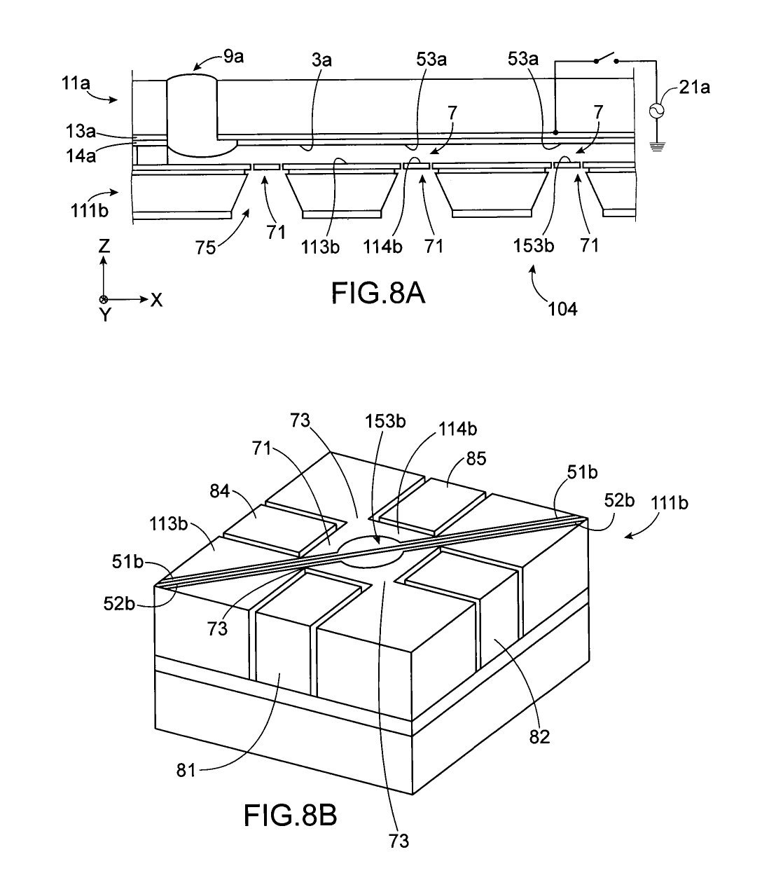

Indeed, FIGS. 8A and 8B diagrammatically show means of electromechanical detection incorporated into a device for handling according to an alternative of the first embodiment. More particularly, FIG. 8A is a longitudinal cross-section diagrammatical view of the device and FIG. 8B is a diagrammatical view in perspective of a portion of the lower substrate of the device of FIG. 8A.

The upper substrate 11a of the device 104 is similar to that which was described previously. Advantageously, the upper substrate 11a comprises a hydrophobic layer 14a formed on the dielectric layer 13a. The hydrophobic layer 14a which thus forms the first surface 3a can be SiOC, PTFE (polytetrafluoroethylene), and even parylene, and have a thickness of a few nanometres to a few microns.

Advantageously, the dielectric layer 13a and the hydrophobic layer 14a can be a single layer of the same material, which can be, for example, Teflon, parylene, SiOC.

The lower substrate 111b comprises a plurality of electromechanical oscillators 71 maintained in the substrate 111b by means of support 73 (FIG. 8B). The upper surface (i.e., the second surface 113b) of the lower substrate 111b thus comprises detection surfaces 114b formed by the surfaces of the oscillators 71.

The oscillators 71 can be similar or identical to those described in international application WO2009/141515, filed in the name of the applicant, describing a device for gravimetric detection of particles in a fluid medium.

Each oscillator 71 is here a square plate arranged above a cavity 75 which allows it to vibrate in its plane and outside of the plane. However, it can have other shapes, for example a disc, a ring, or a polygon.

Each plate 71 is mounted on the lower substrate 111b by means of support 73, contact tops (FIG. 8B) or possibly beams (not shown), distributed at the four tops of the oscillator 71 and oriented according to the diagonals of the latter.

The square plate 71 has a width between 5 and a few hundred microns. Its thickness is typically less than or equal to one-tenth of its width. The square plate 71 can be made from a material chosen from among monocrystalline silicon, polycrystalline silicon, diamond, silicon nitride, silicon oxide, nickel, tungsten, and even platinum or any other material used in the field of electromechanical microsystems or nanosystems (MEMS, NEMS).

The pair of second displacement electrodes 51b, 52b extends over the second surface 113b from a second reservoir (not shown), is extended on the square plate 71 of the oscillator forming a detection surface 114b, by the intermediary of the means of support 73. The pair of second electrodes 51b, 52b forms a second drop forming zone 153b on the detection surface 113b.

Furthermore, the square plate 71 is arranged in a crossover zone 7 directly opposite a first drop forming zone 53a of the first displacement electrodes.

Each oscillator 71 is adapted to be placed into vibration, more preferably at its resonance frequency, via capacitive coupling with actuating electrodes 81, 82 arranged opposite the edge of the oscillator 71.

Note that the oscillator 71 can vibrate, more preferably in its plane, according to a predetermined vibration mode chosen from among the Lame mode, the volume extension mode or the so-called “Wine Glass” mode or any other contour mode.

The gravimetric detection is carried out via capacitive coupling between the oscillator 71 and two measurement electrodes 84, 85 arranged opposite the edge of the oscillator 71.

Using the electric current measured, the difference in frequency between the effective vibration frequency and the initial frequency imposed is deduced.

The mode for forming the first and second fluidic fingers is identical to that which was described previously. In particular, the second fluidic finger is formed through liquid dielectrophoresis and extends over the lower substrate 111b and the oscillators 71 via the corresponding means of support 73.

The second drop forming zones 153b are arranged on each detection surface 114b. As such, at the stopping of the electrical control, the second fluidic finger is ruptured via capillarity into a plurality of second drops, with each being arranged on a second drop forming zone 153b, and as such on a detection surface 114b of the corresponding oscillator 71.

Each of the second drops 23b formed on the detection surfaces 114b interacts with the corresponding drop of the first drops 23a coming from the first surface in order to form a set of global drops on the different detection surfaces 114b. The gravimetric detection then makes it possible to analyse the interactions that are produced inside these drops.

Note that the detection surface 114b of the oscillator 71 can advantageously have a hydrophilic zone intended to be covered by the drop.

Alternatively, the device for handling can comprise electrophysiological means of detecting (not shown).

Indeed, the oscillators 71 in the lower substrate 11b can be replaced with electrophysiological sensors. These sensors record ionic currents transiting through cell membranes forming detection surfaces.

The lower substrate has, on the detection surface, an opening acting as a fluidic chamber, of which one of the walls is the lower surface of the membrane.

Also available are means for measuring the potential difference between two points of measure arranged on either side of the membrane making it possible to measure ionic currents of the species transiting through the membrane between the drop formed on the membrane and the fluidic chamber.

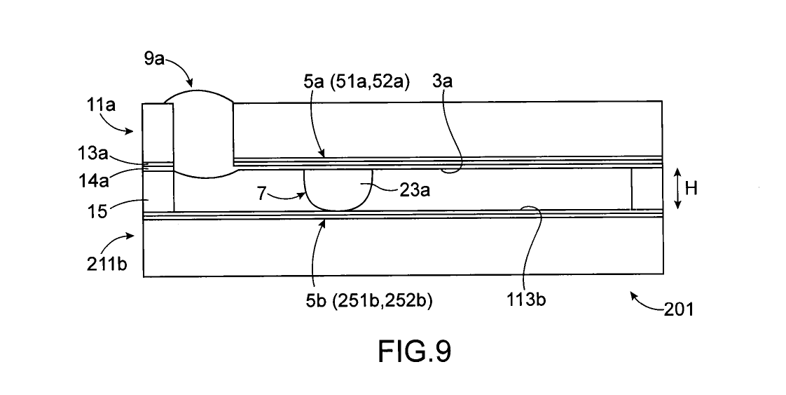

FIG. 9 shows a microfluidic device for handling 201a drop according to a second embodiment of the invention.

The device for handling 201 comprises a lower substrate 211b and an upper substrate 11a forming a cover, arranged opposite one another.

The upper substrate 11a is identical to that which was described previously and as such comprises at least one reservoir 9a of liquid of interest and at least one first electrical displacement path 5a arranged on the first surface 3a. Advantageously, the upper substrate 11a further comprises a hydrophobic layer 14a formed on the dielectric layer 13a.

Each first electrical displacement path 5a comprises a pair of first electrodes 51a, 52a substantially parallel and coplanar arranged on the first surface 3a for the forming through liquid dielectrophoresis under the effect of the electrical activation, of a fluidic finger from the corresponding reservoir 9a of liquid of interest. The fluidic finger is ruptured via capillarity under the effect of the deactivation, by generating at least one drop 23a.

The lower substrate 211b comprises at least one second electrical displacement path 5b arranged on the second surface. The first and second electrical displacement paths define between them at least one crossover zone 7.

Each second electrical displacement path 5b comprises second electrodes 251b, 252b for the displacement of at least one drop 23a formed by the upper substrate 11a in a crossover zone 7.

By way of example, the second electrodes 251b, 252b can be square electrodes configured to displace the drop or drops by EWOD under the effect of an adequate electrical activation of the second electrodes 251b, 252b and of an earthing of the pair of first electrodes 51a, 52a knowing that the drop or drops have a sufficient thickness to be in contact with the first and second electrodes.

Indeed, the spacing distance H between the first surface 3a and the second surface 3b, as well as the dimensions of the first displacement electrodes are adapted in such a way that the maximum thickness of the fluidic finger is less than the distance H and that the drop has a thickness greater than this distance H.

In other terms, let the radius of a fluidic finger be R, then the radius of a drop is of a magnitude of 2R. In this case, the height H separating the first and second surfaces verifies the following inequality:

R<H<2R.

By way of example, for a separation distance of a magnitude of 50 μm, the first electrodes 51a, 52a can have a width w of a magnitude of 20 μm and be separated from each other by a distance g of a magnitude of 20 μm. The radius R of the fluidic finger will be as such of a magnitude of R=w+g/2=30 μm and the radius of a drop will be of a magnitude of 60 μm.

Note that according to this second embodiment, the drops are formed by the upper substrate 11a and as such the lower substrate 111b does not comprise any reservoir of liquid of interest.

The second embodiment according to the invention makes it possible to transfer drops of liquid of the first surface 3a towards the second surface 113b and to handle or then displace this liquid thanks to the displacement electrodes arranged on the second surface.

Advantageously, the device comprises means of optical, electromechanical, electrophysiological or other detection, carried out as described in reference to the first embodiment.

In particular, for the means of electromechanical detection, the second electrodes can be configured for example, to bring the drops onto the detection surfaces.

Furthermore, the second surface can be functionalised, and/or have a temperature that differs from the first surface, and/or comprise biological components for the creation of various biological or chemical protocols.

Of course, various modifications can be made by those skilled in the art to the invention which has just been described, solely by way of non-restricting examples.

1. A microfluidic device for handling a drop, said device comprising:
first and second microfluidic surfaces parallel and separated from each other by a separation distance,
at least one first electrical displacement path arranged on said first surface,
at least one second electrical displacement path arranged on said second surface, said first and second paths defining therebetween at least one crossover zone,
at least one of said first and second paths being configured to form through liquid dielectrophoresis, under the effect of an electrical activation, a respective fluidic finger along said path from a corresponding reservoir of liquid of interest arranged in such a way as to be able to place into contact said liquid with the associated surface, said fluidic finger rupturing via capillarity under the effect of an electrical deactivation, by generating at least one respective drop from said fluidic finger in said at least one crossover zone,
the first and second paths being configured so that said separation distance between said first and second surfaces is on the one hand, greater than the fluidic thickness formed by each fluidic finger and, on the other hand, less than the fluidic thickness formed by each drop.

2. The device according to claim 1, said first electrical displacement path comprising a pair of first electrodes substantially parallel and coplanar arranged on said first surface for the forming under the effect of the electrical activation, of a first fluidic finger from a first reservoir of a first liquid of interest, said second electrical displacement path comprising a pair of second electrodes substantially parallel and coplanar arranged on said second surface for the forming under the effect of the electrical activation, of a second fluidic finger from a second reservoir of a second liquid of interest, said first and second fluidic fingers rupturing via capillarity under the effect of the deactivation, by generating at least one respective first drop and at least one second drop which are mixed in said at least one crossover zone in order to form at least one global drop.

3. The device according to claim 2, said pair of first electrodes comprising a plurality of first drop forming zones, in such a way that at the deactivation of said pair of first electrodes, the first fluidic finger ruptures into a plurality of first drops each located on one of said first drop forming zones.

4. The device according to claim 3, said pair of second electrodes comprising a plurality of second drop forming zones each arranged facing a separate first drop forming zone forming as such a plurality of crossover zones, in such a way that at the deactivation of said pair of second electrodes, the second fluidic finger ruptures into a plurality of second drops each located on one of said second drop forming zones, each second drop coming into contact with the first corresponding drop in order to form a global drop in the corresponding crossover zone.

5. The device according to claim 4, said first surface comprising a first network of m pairs of first electrodes each comprising a series of n first drop forming zones forming as such a first set of nm first drop forming zones, said second surface comprising a second network of n pairs of second electrodes each comprising a series of m second drop forming zones forming as such a second set of nm second drop forming zones, said nm first drop forming zones crossing over said nm second drop forming zones in order to form a set of nm crossover zones.

6. The device according to claim 2, wherein said pair of second electrodes is configured in order to displace at least one second drop and/or at least one global drop located along said pair of second electrodes.

7. The device according to claim 1, said first electrical displacement path comprising a pair of first electrodes substantially parallel and coplanar arranged on said first surface for the forming through liquid dielectrophoresis under the effect of the electrical activation, of a fluidic finger from a reservoir of liquid of interest, said fluidic finger rupturing via capillarity under the effect of the deactivation, by generating at least one drop, said second electrical displacement path comprising second electrodes for the displacement of said at least one drop under the effect of an electrical activation of said second electrodes.

8. The device as claimed in claim 1, further comprising means of detecting a component of a drop formed on said at least one crossover zone.

9. The device according to claim 8, wherein said means of detecting are optical means comprising a light source in order to emit a light on said at least one drop and means of receiving in order to receive the light diffused by said at least one drop.

10. The device according to claim 8, wherein said means of detecting are electromechanical means comprising at least one flat oscillator of which a surface forms a detection surface belonging to one or the other of said first and second surfaces.

11. The device according to claim 10, wherein said detection surface has a hydrophilic zone intended to be covered by said at least one drop.

12. The device according to claim 2, wherein each of said pairs of first and second electrodes is covered with a dielectric layer.

13. A method for handling a drop, the method comprising the following steps:
putting into contact of at least one first reservoir comprising a first liquid of interest with at least one first corresponding electrical displacement path arranged on a first microfluidic surface,
putting into contact of at least one second reservoir comprising a second liquid of interest with at least one second corresponding electrical displacement path arranged on a second microfluidic surface, said first and second surfaces being parallel and separated from each other by a separation distance, said at least one first and at least one second paths of displacement defining between them at least one crossover zone,
activating said at least one first path of displacement, in such a way as to form along said first path a first corresponding fluidic finger,
activating said at least one second path of displacement, in such a way as to form along said second path a second corresponding fluidic finger,
deactivating said at least one first path of displacement, in such a way that the first corresponding fluidic finger is ruptured via capillarity by generating at least one first drop located in said at least one crossover zone,
deactivating said at least one second path of displacement, in such a way that the second fluidic finger is ruptured via capillarity by generating at least one second drop located in said at least one crossover zone, said separation distance between said first and second surfaces being on the one hand, greater than the sum of the thicknesses of said first and second fluidic fingers, and, on the other hand, less than the sum of the thicknesses of said first and second drops, in such a way that said first and second drops are mixed together in said at least one crossover zone in order to form at least one global drop.

14. The method according to claim 13, comprising the following steps:
putting into contact of a set of m first reservoirs comprising m first liquids of interest with a network of m first corresponding paths each comprising a series of n first drop forming zones forming as such a first set of nm first drop forming zones,
putting into contact of a set of n second reservoirs comprising n second liquids of interest with a network of n corresponding second paths each comprising a series of m second drop forming zones forming as such a second set of nm second drop forming zones, said nm first drop forming zones crossing over respectively said nm second drop forming zones in order to form a set of nm corresponding crossover zones,
activating said network of m first paths, in such a way as to form a network of m first corresponding fluidic fingers,
activating of said network of n second paths, in such a way as to form a network of n second corresponding fluidic fingers,
deactivating said network of m first paths, in such a way that the m first corresponding fluidic fingers rupture via capillarity by generating a set of nm first drops in said first set of nm first drop forming zones,
deactivating said network of n second paths, in such a way that the n second corresponding fluidic fingers rupture via capillarity by generating a set of nm second drops in said second set of nm second drop forming zones, the nm first drops mixing with the nm second corresponding drops in order to form a set of nm global drops in the nm corresponding crossover zones.

15. The method according to claim 14, said m first reservoirs comprising respectively m first samples of different properties of a first solution and said n second reservoirs comprising respectively n second samples of different properties of a second solution forming as such nm different global drops.

16. The method according to claim 15, comprising a detection via optical, electromechanical, or electrophysiological means of the different interactions between said first and second solutions.

17. A method for handling a drop, said method comprising the following steps:
putting into contact of at least one reservoir comprising a liquid of interest with at least one first corresponding electrical displacement path arranged on a first microfluidic surface, said first surface being parallel to a second microfluidic surface and separated from the latter by a separation distance, said second surface comprising at least one second electrical displacement path defining at least one crossover zone with said at least one first path,
activating said at least one first path of displacement, in such a way as to form along said first path a corresponding fluidic finger,
deactivating said at least one first path of displacement, in such a way that the corresponding fluidic finger is ruptured by capillarity by generating at least one drop located in said at least one crossover zone, said separation distance between said first and second surfaces being on the one hand, greater than the thickness of said fluidic finger and, on the other hand, less than the thickness of said at least one drop, and
activating said at least one second electrical displacement path, in such a way as to displace said at least one drop.
